(19) United States
(12) Patent Application Publication
(10) Pub. No.: US 2024/0170322 A1
(43) Pub. Date: May 23, 2024

(54) Material Handling Robot

(71) Applicant: Persimmon Technologies Corporation, Wakefield, MA (US)

(72) Inventors: Martin HOSEK, Salem, NH (US); Scott WILKAS, Lexington, MA (US)

(21) Appl. No.: 18/426,659

(22) Filed: Jan. 30, 2024

Related U.S. Application Data
(62) Division of application No. 17/569,696, filed on Jan. 6, 2022, now Pat. No. 11,887,880.
Application No. 17/569,696 is a continuation of application No. 16/818,408, filed on Mar. 13, 2020, now Pat. No. 11,251,065.
Application No. 16/818,408 is a continuation of application No. 16/104,529, filed on Aug. 17, 2018, now Pat. No. 10,629,472.
(60) Provisional application No. 62/548,064, filed on Aug. 21, 2017.
(60) Provisional application No. 62/546,677, filed on Aug. 17, 2017.

(51) Int. Cl. H01L 21/687; B25J 9/04; B25J 9/10; B25J 15/00; B25J 18/04; H01L 21/677

(52) U.S. Cl. CPC H01L 21/68707; B25J 9/043; B25J 9/104; B25J 15/0052; B25J 18/04; H01L 21/67742

(57) ABSTRACT

An apparatus including a first upper arm rotatable about a first shoulder axis; a second upper arm rotatable about the first shoulder axis; a first forearm rotatably connected to the first upper arm; a second forearm rotatably connected to the second upper arm; a first end effector rotatably connected to the first forearm, where the first end effector is configured to support at least one substrate thereon; and a second end effector rotatably connected to the second forearm where the first end effector is configured to support at least one substrate thereon, where the first and second upper arms are configured to rotate in different first and second horizontal planes, where the first and second forearms are configured to rotate in a common different third horizontal plane, and where the first and second end effectors are configured to rotate in a common different fourth horizontal plane.

### CROSS-REFERENCE TO RELATED APPLICATIONS

This application is a divisional of copending application Ser. No. 17/569,696 filed Jan. 6, 2022, which is a continuation of application Ser. No. 16/818,408, filed Mar. 13, 2020, now U.S. Pat. No. 11,251,065, which is a continuation of application Ser. No. 16/104,529 filed Aug. 17, 2018, now U.S. Pat. No. 10,629,472, which claims priority under 35 USC 119 (e) to provisional patent application Ser. No. 62/548,064 filed Aug. 21, 2017, and provisional patent application No. 62/546,677 filed Aug. 17, 2017 which are hereby incorporated by reference in their entireties.

### BACKGROUND

### Technical Field

The exemplary and non-limiting embodiments relate generally to a material-handling robot and, more particularly, to a material-handling robot with multiple end-effectors suitable such as for applications in semiconductor wafer processing systems.

### BRIEF DESCRIPTION OF PRIOR DEVELOPMENTS

Material-handling robots, such as for applications in semiconductor wafer processing systems for example, are known. Some examples may be found in the following U.S. patents and patent publications (which are hereby incorporated by reference in their entireties): U.S. Pat. No. 9,149,936 which discloses how non-circular pulleys may be calculated; U.S. Patent Publication No. US 2016/0167229 A1; and U.S. Patent Publication No. US 2017/0028546 A1.

### SUMMARY

The following summary is merely intended to be exemplary. The summary is not intended to limit the scope of the claims.

In accordance with one aspect, an example embodiment is provided in an apparatus comprising a controller comprising a processor and a memory comprising computer code; a robot drive coupled to the controller, where the controller is configured to control actuation of the robot drive; a robot arm connected to the robot drive, where the robot arm comprises links including an upper arm, a first forearm connected to a first end of the upper arm, a second forearm connected to a second opposite end of the upper arm, a first end effector connected to the first forearm and a second end effector connected to the second forearm; and a transmission connecting the robot drive to the first and second forearms and the first and second end effectors, where the transmission is configured to rotate the first and second forearms relative to the upper arm and rotate the first and second end effectors on their respective first and second forearms, where the upper arm is substantially rigid such that movement of the upper arm by the robot drive moves both the first and second forearms in opposite directions, where the controller and the transmission are configured to coordinate movement and rotation of the links relative to one another to move the end effectors into and out of a station comprising: moving the first forearm relative to the upper arm, while the upper arm remains substantially stationary, to move the first end effector into an entrance path of the station, and subsequently rotating the upper arm and the first forearm to move the first end effector along the entrance path in a substantially straight line into the station.

In accordance with another aspect, an example method may comprise connecting a controller to a robot drive; connecting an upper arm to a first drive shaft of the robot drive; connecting a first forearm to an end of an upper arm; connecting a second forearm to an opposite end of the upper arm; connecting a first end effector to the first forearm; connecting a second end effector to the second forearm; connecting a first transmission belt arrangement between a second drive shaft of the robot drive and the first forearm; connecting a second transmission belt arrangement between the first forearm and the first end effector, where the second transmission belt arrangement is configured to rotate the first end effector relative to the first forearm when the first forearm is rotated relative to the upper arm, where the controller and the transmission belt arrangements are configured to coordinate movement of the upper arm and the first forearm on the upper arm relative to each another to move the first end effector into a station comprising: a first path comprising moving the first forearm relative to the upper arm, while the upper arm remains substantially stationary, to move the first end effector into a starting location of a second entrance path for the station, and the second entrance path comprising subsequently rotating the upper arm and the first forearm on the upper arm to move the first end effector along the second entrance path in a substantially straight line into the station.

In accordance with another aspect, an example method may comprise moving a first end effector along a first path from a first location to a second location, where the second location is a start of a subsequent second substantially straight entrance path into a substrate processing module, where the first end effector is connected to an end of a first forearm of a robot arm, where the first end effector is moved along the first path by rotating the first forearm on an upper arm of the robot arm by a robot drive while the upper arm remains substantially stationary, and rotating the first end effector relative to the first forearm as the first forearm is rotated on the upper arm, where the robot arm comprises a transmission belt arrangement connected between the first end effector and the first forearm to automatically mechanically rotate the first end effector relative to the first forearm as the first forearm is rotated on the upper arm; and moving the first end effector from the second location into the substrate processing module along the second substantially straight entrance path, where the second substantially straight entrance path is maintained by rotating the upper arm by the robot drive to move the first forearm towards the substrate processing module and simultaneously rotating the first forearm on the upper arm while the transmission belt arrangement automatically mechanically rotates the first end effector relative to the first forearm, as the first forearm is rotated on the upper arm, to maintain the first end effector in a substantially straight line into the substrate processing module.

### BRIEF DESCRIPTION OF THE DRAWINGS

The foregoing aspects and other features are explained in the following description, taken in connection with the accompanying drawings, wherein:

FIG. 1A is a top view of an example embodiment of a robot;

FIG. 1B is a side view of the robot shown in FIG. 1A;

FIG. 2 is a diagram illustrating drive and transmission connections in the robot shown in FIGS. 1A-1B;

FIGS. 3A-3B are diagrams illustrating example movement of the robot of FIGS. 1-2 in a substrate processing system;

FIGS. 4A-4D are diagrams illustrating example movement of the robot of FIGS. 1-2 in the substrate processing system shown in FIGS. 3A-3B;

FIG. 5A is a top view of an example embodiment of a robot;

FIG. 5B is a side view of the robot shown in FIG. 5A;

FIG. 6 is a diagram illustrating drive and transmission connections in the robot shown in FIGS. 5A-5B;

FIGS. 7A-7B are diagrams illustrating example movement of the robot of FIGS. 5-6 in a substrate processing system;

FIGS. 8A-8D are diagrams illustrating example movement of the robot of FIGS. 5-6 in the substrate processing system shown in FIGS. 7A-7B;

FIG. 9A is a top view of an example embodiment of a robot;

FIG. 9B is a side view of the robot shown in FIG. 9A;

FIG. 10 is a diagram illustrating drive and transmission connections in the robot shown in FIGS. 9A-9B;

FIGS. 11A-11B are diagrams illustrating example movement of the robot of FIGS. 9-10 in a substrate processing system;

FIGS. 12A-12D are diagrams illustrating example movement of the robot of FIGS. 9-10 in the substrate processing system shown in FIGS. 11A-11B;

FIG. 13A is a top view of an example embodiment of a robot;

FIG. 13B is a side view of the robot shown in FIG. 13A;

FIG. 14 is a diagram illustrating drive and transmission connections in the robot shown in FIGS. 13A-13B;

FIGS. 15A-15B are diagrams illustrating example movement of the robot of FIGS. 13-14 in a substrate processing system;

FIGS. 16A-16D are diagrams illustrating example movement of the robot of FIGS. 13-14 in the substrate processing system shown in FIGS. 15A-15B;

FIGS. 17A-17D are diagrams illustrating example movement of the robot of FIGS. 13-14 in the substrate processing system shown in FIGS. 15A-15B;

FIG. 18A is a top view of an example embodiment of a robot;

FIG. 18B is a side view of the robot shown in FIG. 18A;

FIG. 19 is a diagram illustrating drive and transmission connections in the robot shown in FIGS. 18A-18B;

FIGS. 20A-20B are diagrams illustrating example movement of the robot of FIGS. 18-19 in a substrate processing system;

FIGS. 21A-21E are diagrams illustrating example movement of the robot of FIGS. 18-19 in the substrate processing system shown in FIGS. 20A-20B;

FIGS. 22A-22B illustrate some examples of circular and non-circular pulleys in belt/band transmissions; and

FIG. 23 is a diagram illustrating two different paths of movement of the first end effector shown FIGS. 21A-21C.

### DETAILED DESCRIPTION OF EMBODIMENTS

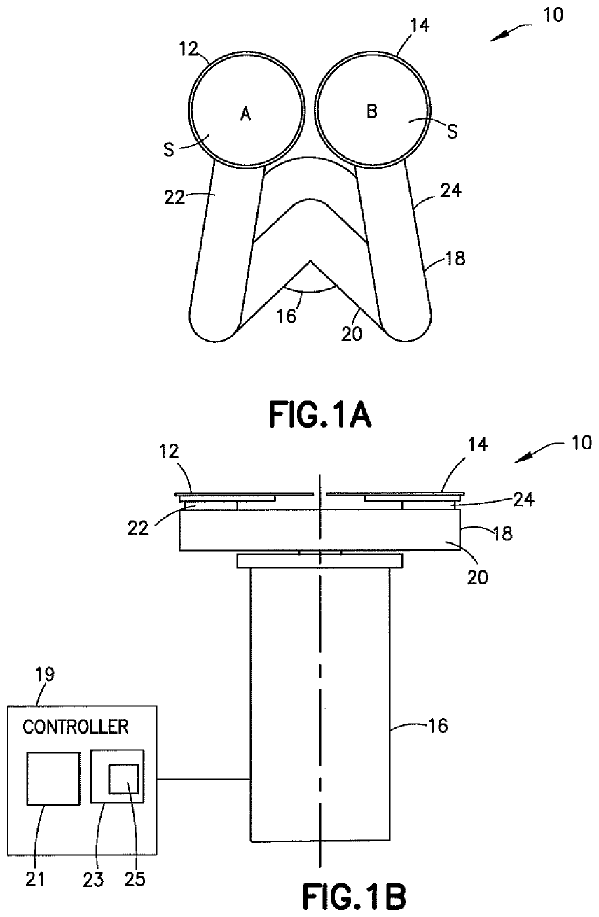

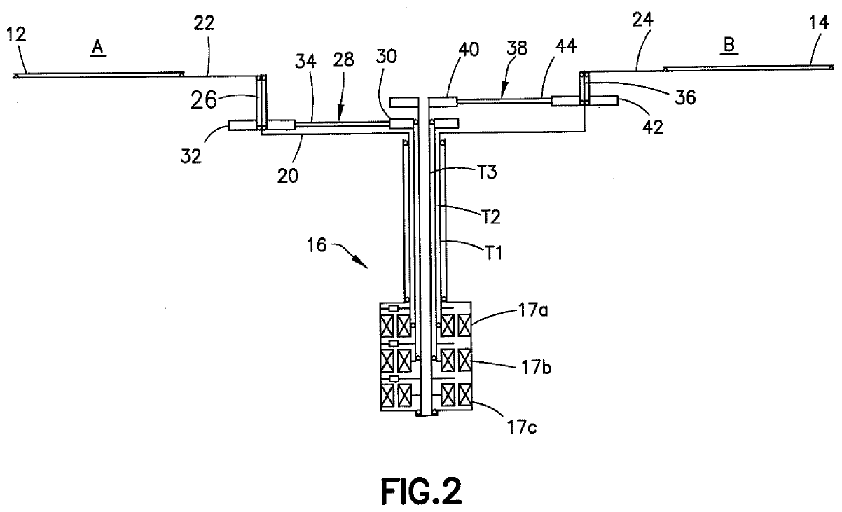

Referring to FIGS. 1A-1B, an example embodiment of a robot 10 comprising features as described herein is shown. The robot 10 in this example comprises two end-effectors 12, 14 configured to support substrates S thereon. In the various figures, the left end effector 12 is shown with the indicator “A” and the right end effector is shown with the indicator “B”. FIG. 1A shows a top view of the robot 10 and FIG. 1B depicts a side view of the robot 10. The robot 10 comprises of a robot drive unit 16 and a robot arm 18. The drive unit 16 is coupled to a controller 19 which may comprise, for example, at least one processor 21 and at least one memory 23 comprising computer code 25 for controlling the drive 16 and receiving sensor signals from sensors in the drive 16 as well as other sensors and inputs (not shown). Although features will be described with reference to the example embodiments shown in the drawings, it should be understood that features can be embodied in many alternate forms of embodiments. In addition, any suitable size, shape or type of elements or materials could be used.

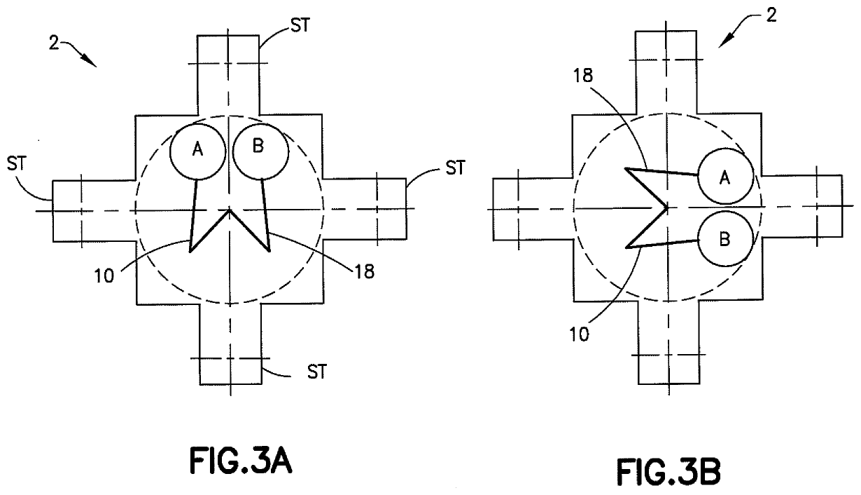

The robot arm 18 comprises an upper arm 20, a left forearm 22 with the left end-effector 12 and a right forearm 24 with the right end-effector 14. Referring also to FIG. 2, the robot arm may be driven by the robot drive unit 16. In this example embodiment, the robot drive unit 16 comprises a three-axis spindle with three coaxial shafts; an outer T1 shaft, a middle T2 shaft and an inner T3 shaft. The robot drive unit 16 comprises three motors 17a, 17b, 17c for axially rotating the drive shafts T1, T2, T3.

The upper arm 20 of the robot arm 18 may be attached directly to the T1 shaft. The left forearm 22 may be coupled to the upper arm 20 via a rotary joint (elbow joint 26), and actuated by the T2 shaft using a belt arrangement 28. The belt arrangement 28 may comprise a shoulder pulley 30, which may be attached to the T2 shaft, elbow pulley 32, which may be attached to the left forearm 22, and a band, belt or cable 34, which may transmit motion between the two pulleys 30, 32. The belt arrangement may feature a constant or variable transmission ratio. As an example, a variable transmission ratio may be implemented using non-circular pulleys.

Similarly, the right forearm 24 may be coupled to the upper arm 20 via a rotary joint (elbow joint 36), and its orientation may be controlled by the T3 shaft using another band, belt or cable arrangement 38. The belt arrangement 38 may comprise a shoulder pulley 40, which may be attached to the T3 shaft, an elbow pulley 42, which may be attached to the right forearm 24, and a band, belt or cable 44, which may transmit motion between the two pulleys 40, 42. Again, the belt arrangement 38 may feature a constant or variable transmission ratio, for example, implemented through the use of non-circular pulleys.

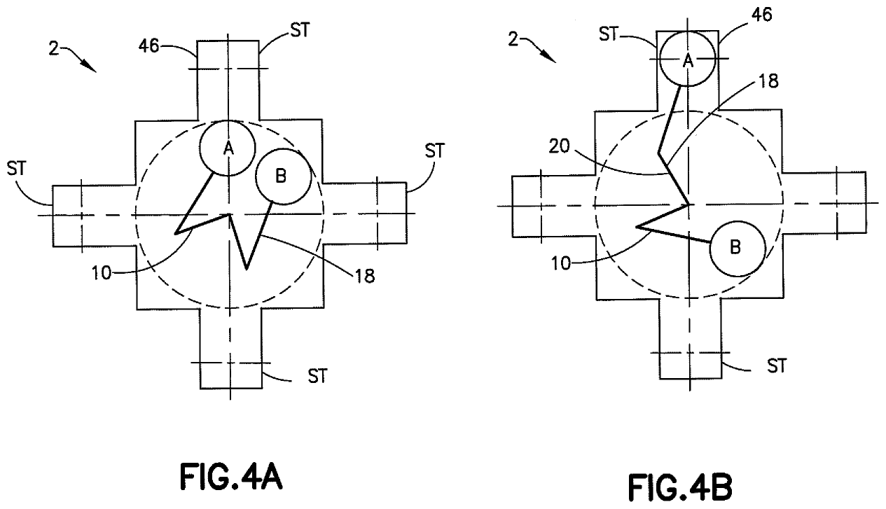

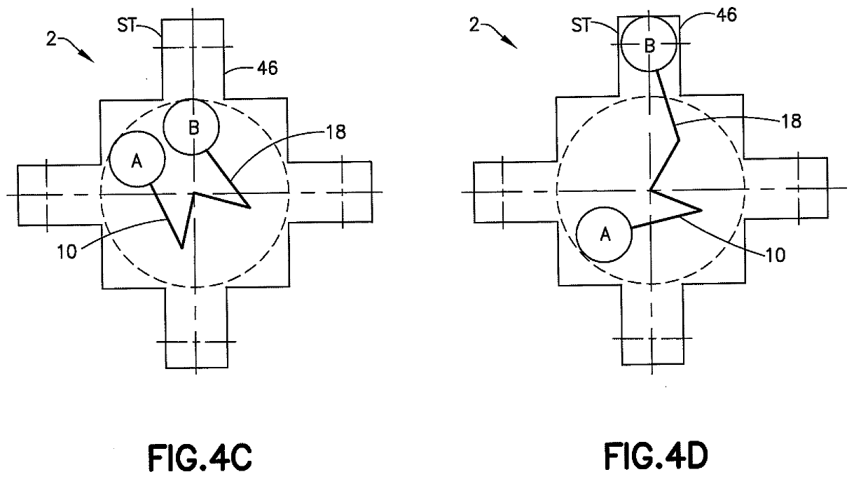

The T1, T2 and T3 shafts of the robot drive unit 16 may be rotated so that the left end-effector A 12 and right end-effector B 14 can access various stations ST, as illustrated diagrammatically in FIGS. 3 and 4, which show diagrams of the robot 10 in an example semiconductor wafer processing system 2.

In order for the entire robot arm 18 to rotate, all drive shafts, i.e., T1, T2 and T3, need to move in the desired direction of rotation of the arm by the same amount with respect to a fixed reference frame. This is depicted diagrammatically by FIGS. 3A and 3B. In this particular example, the entire robot arm 18 rotates in the clockwise direction by 90 degrees.

In order for the left end-effector A to extend from the retracted position shown in FIG. 4A to a station along a predefined path, such as a straight-line radial path, as depicted diagrammatically in the example of FIG. 4B, shafts T1 and T2 may rotate in a coordinated manner in the clockwise and counterclockwise directions, respectively. The inverse kinematic equations for the left end-effector A 12 may be utilized to determine the orientation of the T1 and T2 shafts as a function of the position of the left end-effector A 12. As illustrated in FIG. 4B, the right end-effector B 14 may rotate out in sync with the upper arm 20 as the left end-effector A 12 extends to the station ST 46. The left end-effector A may be retracted by rotating the T1 and T2 shafts backward in a similar manner.

In order for the right end-effector B 14 to extend from the retracted position of FIG. 4C to the same station ST 46 along a predefined path, such as a straight-line radial path, as depicted diagrammatically in the example of FIG. 4D, shafts T1 and T3 may rotate in a coordinated manner in the counterclockwise and clockwise directions, respectively, in accordance with the inverse kinematic equations for the right end-effector B 14. As illustrated in the FIG. 4D, the left end-effector A 12 may swing out in sync with the upper arm 20 as the right end-effector B extends to the station. The right end-effector B 14 may be retracted by rotating the T1 and T3 shafts backward in a similar manner.

The above operations may be utilized to pick/place a wafer from/to a station. A sequence of a pick operation with one end-effector followed by a place operation with the other end-effector may be used to quickly exchange a wafer at a station (rapid exchange operation). As an example, the left end-effector A may be extended to a station, pick a wafer, and retract. The right end-effector B, which may carry another wafer, may then extend to the same station, place the wafer, and retract.

The robot drive unit 16 may include a vertical lift mechanism to control the vertical elevation of the robot arm, which may be used to access stations at different elevations, compensate for the vertical distance between the end-effectors of the robot arm if the end-effectors are not coplanar, and facilitate material pick/place operations.

Although the illustrations of the example embodiment show the left forearm of the robot driven by the T2 shaft and the right forearm of the robot driven by the T3 shaft, any suitable driving schemes and transmission arrangements may be used. Similarly, while straight lines are used to represent the example embodiment in the figures, the upper arm, forearms and end-effectors may feature any for instance, to avoid interference with obstacles in the workspace of the robot.

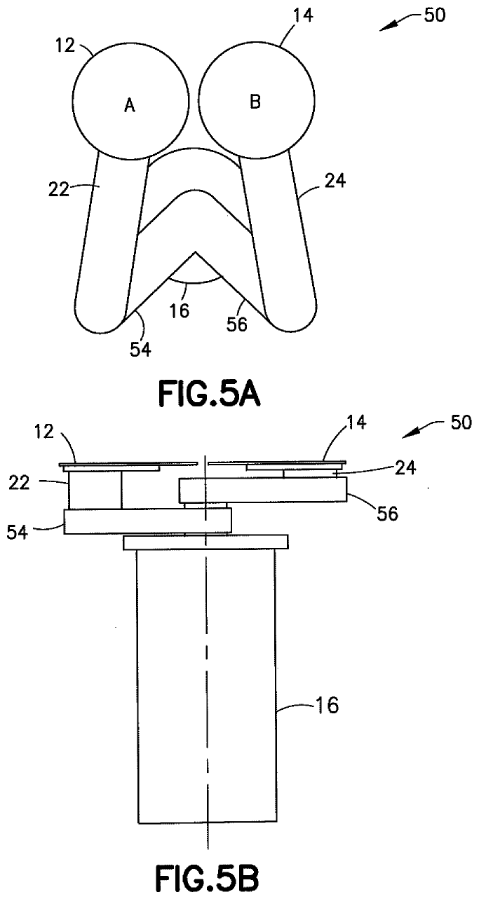

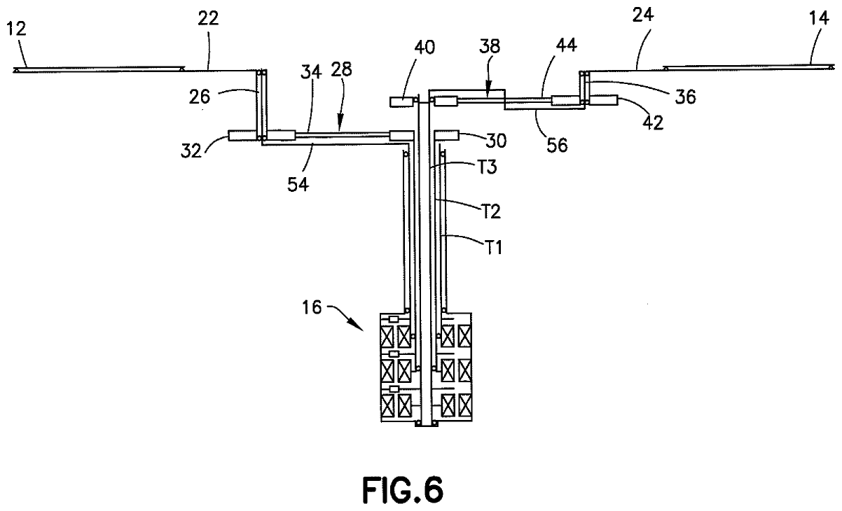

Another example embodiment of a robot with two end-effectors is depicted diagrammatically in FIGS. 5A-5B. FIG. 5A shows the top view of the robot 50 and FIG. 5B depicts the side view of the robot 50. The robot 50 comprises the robot drive unit 16 and a robot arm 52. The robot arm 52 in this example features two linkages, i.e., a left linkage and a right linkage. The left linkage comprises a left upper arm 54 and a left forearm 22 with a left end-effector A 12. Similarly, the right linkage comprises a right upper arm 56 and a right forearm 24 with a right end-effector B 14.

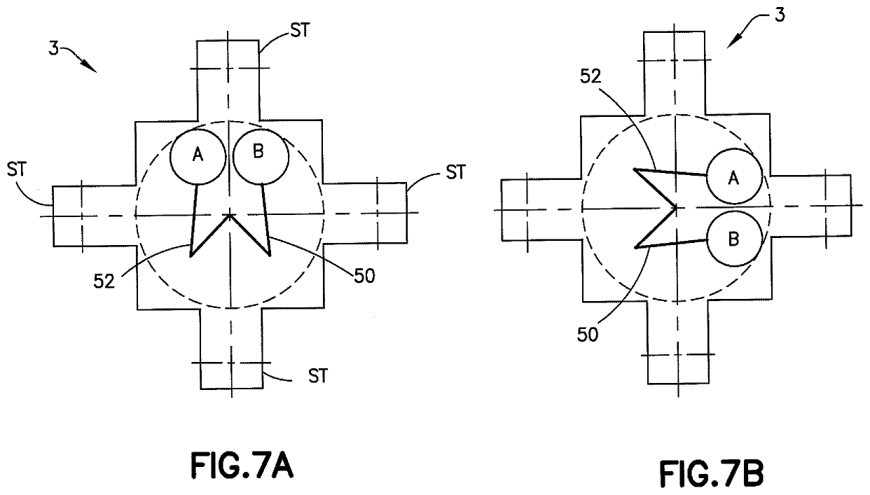

An example internal arrangement of the robot is depicted diagrammatically in FIG. 6. The robot arm 52 is configured to be driven by the robot drive unit 16 with a three-axis spindle with three coaxial shafts, e.g., an outer T1 shaft, a T2 shaft and an inner T3 shaft.

The left upper arm 54 of the robot arm 52 is shown attached directly to the T1 shaft in this example. The left forearm 22 is coupled to the left upper arm 54 via a rotary joint (left elbow joint) 26, and actuated by the T2 shaft using the belt arrangement 28. The belt arrangement 28 in this example comprises a left shoulder pulley 30, which may be attached to the T2 shaft, a left elbow pulley 32, which may be attached to the left forearm 22, and a band, belt or cable 34, which is configured to transmit motion between the two pulleys 30, 32. The belt arrangement 28 may feature a constant or variable transmission ratio. As an example, the variable transmission ratio may be selected so that the orientation of the left forearm 22 with the left end-effector A 12 changes in a predefined manner as a function of the relative position of the left upper arm 54 and the T2 shaft. However, any other suitable arrangement may be used.

Similarly, the right upper arm 56 of the robot arm 52 is shown attached directly to the T3 shaft in this example. The right forearm 24 may be coupled to the right upper arm 56 via the rotary joint (right elbow joint) 36, and actuated by the T2 shaft using the belt arrangement 38. The belt arrangement 38 may comprise the right shoulder pulley 40, which may be attached to the T2 shaft, the right elbow pulley 42, which may be attached to the right forearm 24, and the band, belt or cable 44, which may transmit motion between the two pulleys 40, 42. The belt arrangement 38 may feature a constant or variable transmission ratio. As an example, the variable transmission ratio may be selected so that the orientation of the right forearm with the right end-effector B 14 changes in a predefined manner as a function of the relative position of the right upper arm 56 and the T2 shaft. However, any other suitable arrangement may be used.

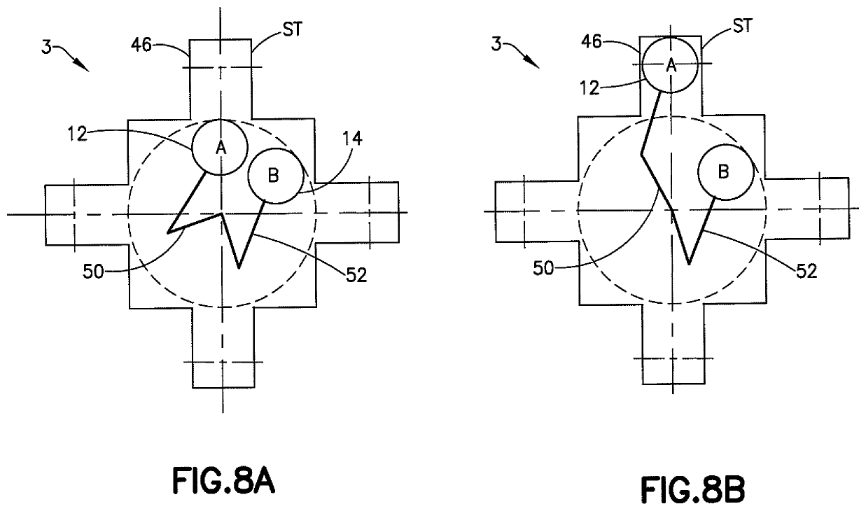

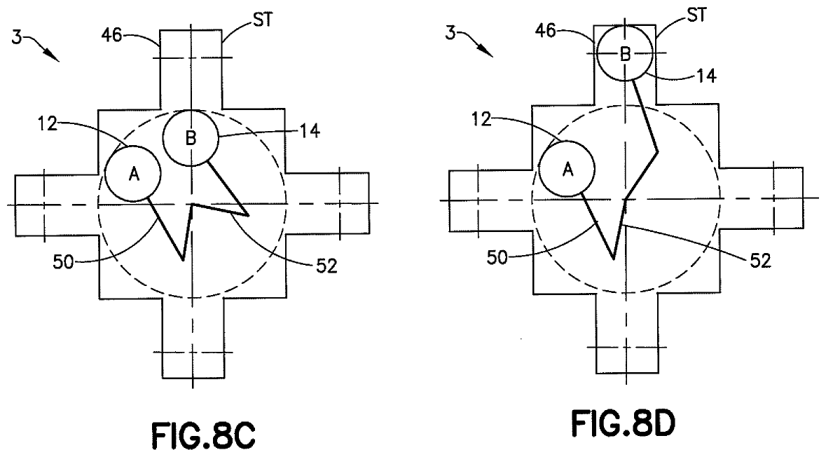

The T1, T2 and T3 shafts of the robot drive unit 16 may be rotated so that the left end-effector A 12 and right end-effector B 14 can access various stations ST, as illustrated diagrammatically in FIGS. 7 and 8, which show diagrams of the robot 50 in an example semiconductor wafer processing system 3.

In order for the entire robot arm 52 to rotate, all drive shafts, i.e., T1, T2 and T3, need to move in the desired direction of rotation of the arm by the same amount with respect to a fixed reference frame. This is depicted diagrammatically in FIGS. 7A-7B. In this particular example, the entire robot arm 52 is shown rotated in the clockwise direction by 90 degrees.

In order for the left end-effector A 12 to extend from the retracted position of FIG. 8A to a station ST 46 along a predefined path, such as a straight-line radial path for example, as depicted diagrammatically in the example of FIG. 8B, shaft T1 may rotate in the clockwise direction while shaft T2 may be held stationary. As illustrated in FIGS. 8A-8B, unlike the example shown in FIGS. 4A-4B, the right end-effector B 14 may remain stationary as the left end-effector A 12 extends to the station ST 46. The left end-effector A 12 may be retracted by rotating the T1 shaft backward in a similar manner.

In order for the right end-effector B 14 to extend from the retracted position of FIG. 8C to the same station ST 46 along a predefined path, such as a straight-line radial path for example, as depicted diagrammatically in the example of FIGS. 8C-8D, shafts T3 may rotate in the counterclockwise direction while shaft T2 may be held stationary. As illustrated, the left end-effector A 12 may remain stationary as the right end-effector B 14 extends to the station ST 46. The right end-effector B 14 may be retracted by rotating the T3 shaft backward in a similar manner.

The above operations may be utilized to pick/place a wafer from/to a station. A sequence of a pick operation with one end-effector followed by a place operation with the other end-effector may be used to quickly exchange a wafer at a station (rapid exchange operation). As an example, the left end-effector A 12 may be extended to a station, pick a wafer, and retract. The right end-effector B 14, which may carry another wafer, may then extend to the same station, place the wafer, and retract.

The robot drive unit 16 may include a vertical lift mechanism to control the vertical elevation of the robot arm 52, which may be used to access stations at different elevations, compensate for the vertical distance between the end-effectors of the robot arm if the end-effectors are not coplanar, and facilitate material pick/place operations.

Although the illustrations of the example embodiment show the robot 50 with the left upper arm 22 below the right upper arm 24, and the left and right end-effectors are depicted at the same elevation (coplanar), in alternate embodiments the upper arms and end-effectors may be arranged in various configurations and elevations. Similarly, although the example embodiment shows the left upper 54 of the robot 50 driven by the T1 shaft and the right upper arm 56 of the robot driven by the T3 shaft, any suitable driving schemes and transmission arrangements may be used. Furthermore, while straight lines are used to represent the example embodiment in the figures, the upper arms, forearms and end-effectors may feature any suitable shapes, for instance, to avoid interference with obstacles in the workspace of the robot.

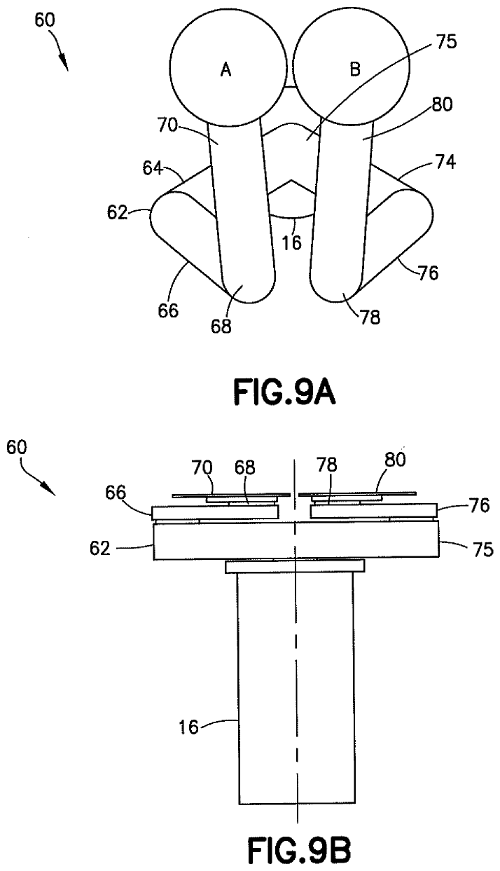

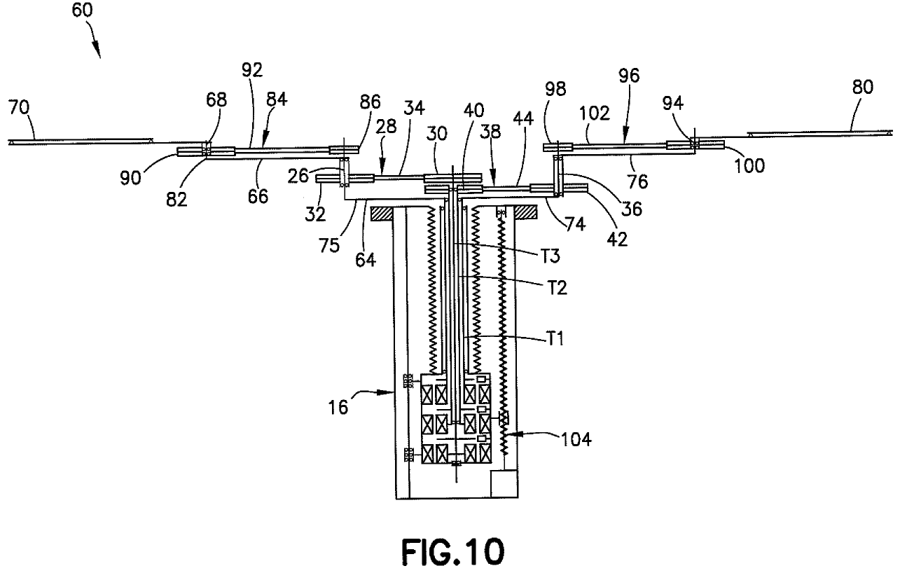

Another example embodiment of a robot with two end-effectors is depicted diagrammatically in FIGS. 9A-9B. FIG. 9A shows a top view of a robot 60 and FIG. 9B depicts a side view of the robot 60. The robot 60 may comprise the robot drive unit 16 and a robot arm 62. The robot arm 62 may feature two linkages, i.e., a left linkage and a right linkage.

The left linkage in this example comprises an upper arm 64, a left forearm 66 and left wrist 68 with a left end-effector A 70. Similarly, the right linkage in this example comprises a upper arm 74, a right forearm 76 and a right wrist 78 with a right end-effector B 80. The upper arms 64, 74 of the left and right linkages are rigidly connected together, and can be viewed as a single shared link 75.

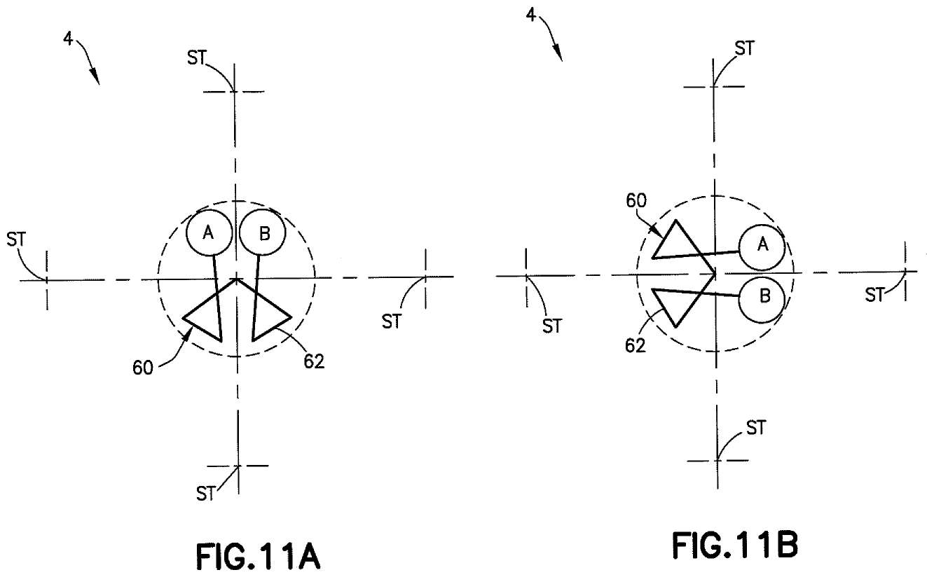

An example internal arrangement of the robot 60 is depicted diagrammatically in FIG. 10. The robot arm 62 may be driven by the robot drive unit 16 with a three-axis spindle with three coaxial shafts, e.g., an outer T1 shaft, a T2 shaft and an inner T3 shaft.

The upper arm link 75 of the robot arm 62 may be attached directly to the T1 shaft. The left forearm 66 may be coupled to the upper arm link 75 via a rotary joint (left elbow joint) 26, and actuated by the T2 shaft using a belt arrangement 28. The belt arrangement 28 may comprise a left shoulder pulley 30, which may be attached to the T2 shaft, a left elbow pulley 32, which may be attached to the left forearm 66, and a band, belt or cable 34, which may transmit motion between the two pulleys 30, 32.

The left wrist 68 with the left end-effector A 70 may be coupled to the left forearm 66 via a rotary joint (left wrist joint) 82, and rotationally constrained by another belt arrangement 84. The belt arrangement 84 may comprise a second left elbow pulley 86, which may be attached to the upper arm 64, a left wrist pulley 90, which may be attached to the left wrist 68, and a band, belt or cable 92, which may transmit motion between the two pulleys 86, 90. The belt arrangement 84 may feature a variable transmission ratio. As an example, the variable transmission ratio may be selected so that the orientation of the left wrist 68 changes in a predefined manner as a function of the relative angle of the upper arm 64 and the left forearm 66. However, any other suitable arrangement may be used.

The right linkage may be conceptually viewed as a mirror image of the left linkage. The right forearm 76 may be coupled to the upper arm 74 via a rotary joint (right elbow joint) 36, and actuated by the T3 shaft using a belt arrangement 38. The belt arrangement 38 may comprise a right shoulder pulley 40, which may be attached to the T3 shaft, a right elbow pulley 42, which may be attached to the right forearm 76, and a band, belt or cable 44, which may transmit motion between the two pulleys 40, 42.

The right wrist 78 with the right end-effector B 80 may be coupled to the right forearm 76 via a rotary joint (right wrist joint) 94, and rotationally constrained by another belt arrangement 96. The belt arrangement 96 may comprise a second right elbow pulley 98, which may be attached to the upper arm 74, a right wrist pulley 100, which may be attached to the right wrist 78, and a band, belt or cable 102, which may transmit motion between the two pulleys 98, 100. The belt arrangement 96 may feature a variable transmission ratio. As an example, the variable transmission ratio may be selected so that the orientation of the right wrist 78 changes in a predefined manner as a function of the relative angle of the right upper arm 74 and the right forearm 76. However, any other suitable arrangement may be used.

As an example, the variable-transmission belt arrangements may be conveniently designed so that, as the arm extends from its retracted position to a station, the orientation of the end-effector gradually aligns with the radial path to the station and then remains unchanged relative to the radial path to the station. Consequently, the relative orientation of the end-effector may be the same when the arm is extended to stations in different radial locations.

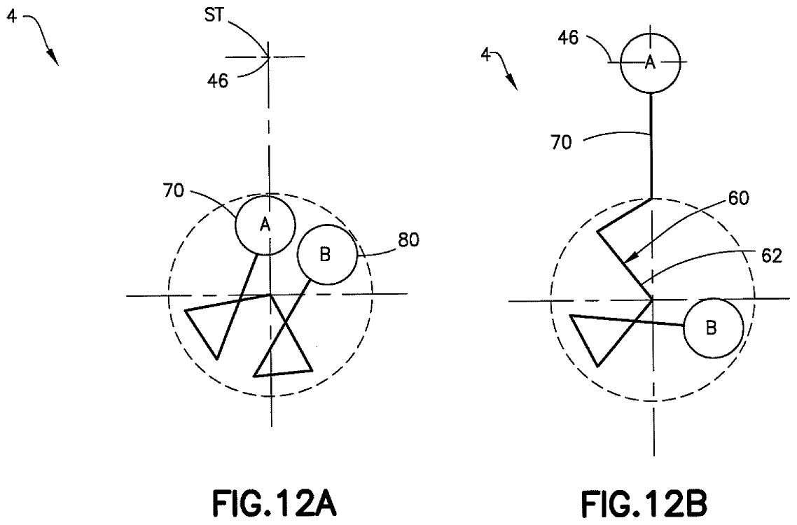

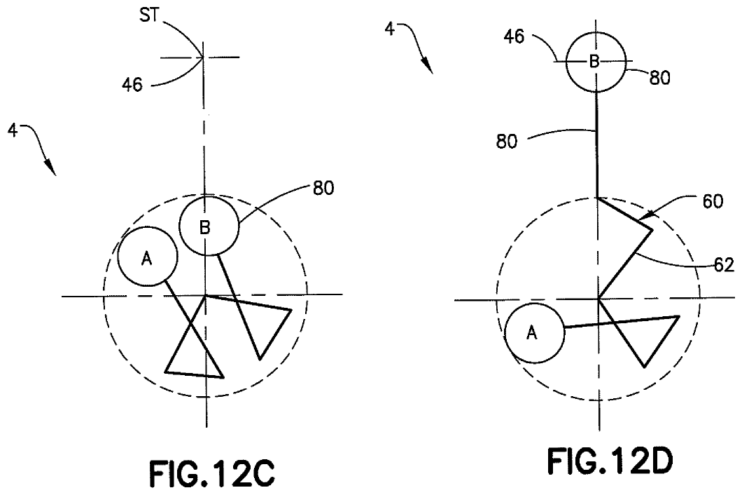

The T1, T2 and T3 shafts of the robot drive unit may be rotated so that the left end-effector A and right end-effector B can access various stations, as illustrated diagrammatically in FIGS. 11-12, which show diagrams of the robot 60 in an example semiconductor wafer processing system 4.

In order for the entire robot arm to rotate, all drive shafts, i.e., T1, T2 and T3, need to move in the desired direction of rotation of the arm 62 by the same amount with respect to a fixed reference frame. This is depicted diagrammatically in FIGS. 11A-11B. In this particular example, the entire robot arm 62 rotates in the clockwise direction by 90 degrees.

In order for the left end-effector A 70 to extend from the retracted position of FIG. 12A to a station ST 46 along a predefined path, such as a straight-line radial path for example, as depicted diagrammatically in the example of FIG. 12B, shaft T1 may rotate in the clockwise direction while shaft T2 may be held stationary. As illustrated in FIGS. 12A-12B, the right end-effector B 80 may rotate as the left end-effector A 70 extends to the station ST 46. In an example embodiment the variable-transmission belt arrangements may be conveniently designed so that the orientation of the left end-effector does not change with extension over the final portion of the move, which means that the relative orientation of the end-effector may be the same when extended to stations in different radial locations. The left end-effector A 70 may be retracted by rotating the T1 shaft backward in a similar manner.

In order for the right end-effector B 80 to extend from the retracted position of FIG. 12C to the same station along a predefined path, such as a straight-line radial path for example, as depicted diagrammatically in the example of FIG. 12D, shafts T3 may rotate in the counterclockwise direction while shaft T2 may be held stationary. As illustrated in the figures, the left end-effector A 70 may rotate as the right end-effector B 80 extends to the station ST 46. In an example embodiment the variable-transmission belt arrangements may be conveniently designed so that the orientation of the left end-effector does not change with extension over the final portion of the move, which means that the relative orientation of the end-effector may be the same when extended to stations in different radial locations. The right end-effector B 80 may be retracted by rotating the T3 shaft backward in a similar manner.

The above operations may be utilized to pick/place a wafer from/to a station ST. A sequence of a pick operation with one end-effector followed by a place operation with the other end-effector may be used to quickly exchange a wafer at a station (rapid exchange operation). As an example, the left end-effector A 70 may be extended to a station, pick a wafer, and retract. The right end-effector B 80, which may carry another wafer, may then extend to the same station, place the wafer, and retract.

As depicted diagrammatically in FIG. 10, the robot drive unit may include a vertical lift mechanism 104 to control the vertical elevation of the robot arm 60, which may be used to access stations ST at different elevations, compensate for the vertical distance between the end-effectors of the robot arm if the end-effectors are not coplanar, and facilitate material pick/place operations.

Although the illustrations of the example embodiment show the robot 60 with the left upper arm below the right upper arm, and the left and right end-effectors are depicted at the same elevation (coplanar), the upper arms and end-effectors may be arranged in various configurations and elevations. Similarly, although the example embodiment shows the left upper of the robot 60 driven by the T1 shaft and the right upper arm of the robot driven by the T3 shaft, any suitable driving schemes and transmission arrangements may be used. Furthermore, while straight lines are used to represent the example embodiment in the figures, the upper arms, forearms and end-effectors may feature any suitable shapes, for instance, to avoid interference with obstacles in the workspace of the robot.

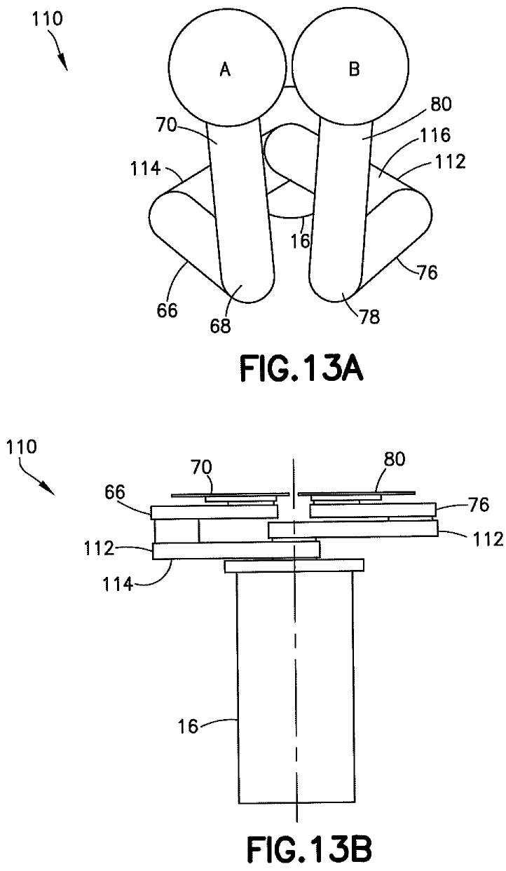

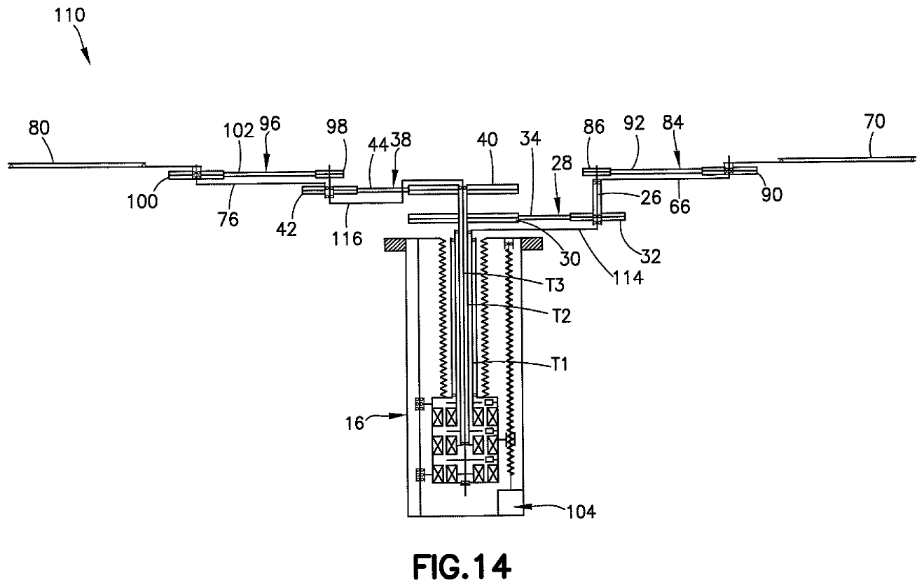

Another example embodiment of a robot with two end-effectors is depicted diagrammatically in FIGS. 13A-13B. FIG. 13A shows a top view of the robot 110 and FIG. 13B depicts a side view of the robot 110. The robot 110 may consist of a robot drive unit 16 and a robot arm 112. The robot arm 112 may feature two linkages, i.e., a left linkage and a right linkage.

The left linkage in this example comprises a left upper arm 114, the left forearm 66 and left wrist 68 with the left end-effector A 70. Similarly, the right linkage in this example comprises a right upper arm 116, the right forearm 76 and the right wrist 78 with the right end-effector B 80.

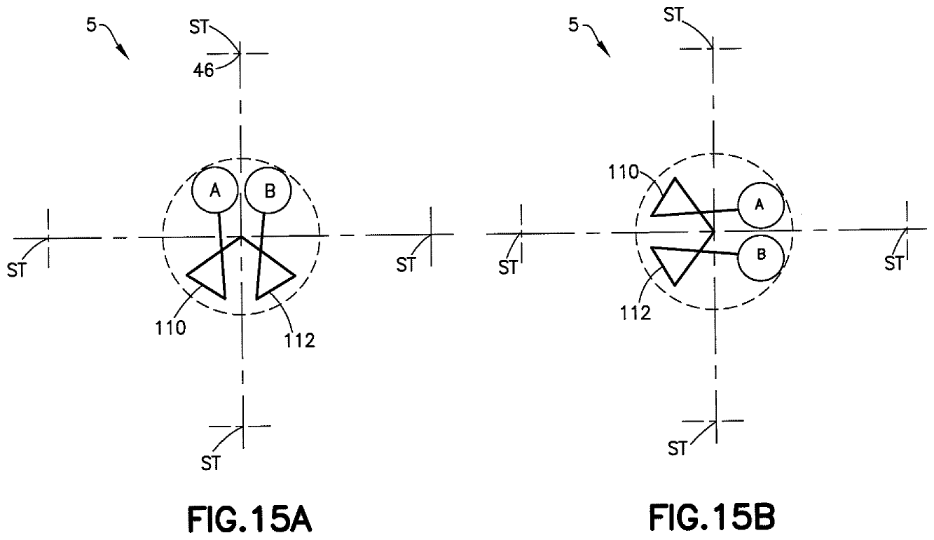

An example internal arrangement of the robot is depicted diagrammatically in FIG. 14. The robot arm 112 may be driven by the robot drive unit 16 with a three-axis spindle with three coaxial shafts, e.g., an outer T1 shaft, a T2 shaft and an inner T3 shaft.

The left upper arm 114 of the robot arm 112 may be attached directly to the T1 shaft. The left forearm 66 may be coupled to the left upper arm 114 via a rotary joint (left elbow joint) 26, and actuated by the T2 shaft using a belt arrangement 28. The belt arrangement 28 may comprise a left shoulder pulley 30, which may be attached to the T2 shaft, a left elbow pulley 32, which may be attached to the left forearm, and a band, belt or cable 34, which may transmit motion between the two pulleys 30, 32. The belt arrangement 28 may feature a variable transmission ratio. As an example, the variable transmission ratio may be selected so that the orientation of the left forearm 66 changes in a predefined manner as a function of the relative position of the left upper arm 114 and the T2 shaft. However, any other suitable arrangement may be used.

The left wrist 78 with the left end-effector A 70 may be coupled to the left forearm 66 via a rotary joint (right wrist: joint), and rotationally constrained by another belt arrangement 84. The belt arrangement 84 may comprise a second left elbow pulley 86, which may be attached to the left upper arm 114, a left wrist pulley 90, which may be attached to the left wrist 68, and a band, belt or cable 92, which may transmit motion between the two pulleys 86, 90. The belt arrangement 84 may feature a variable transmission ratio. As an example, the variable transmission ratio may be selected so that the orientation of the left wrist changes in a predefined manner as a function of the relative angle of the left upper arm and the left forearm. However, any other suitable arrangement may be used.

The right linkage may be conceptually viewed as a mirror image of the left linkage. The right upper arm 116 of the robot arm 112 may be attached directly to the T3 shaft. The right forearm 76 may be coupled to the right upper arm 112 via a rotary joint (right elbow joint), and actuated by the T2 shaft using a belt arrangement 38. The belt arrangement 38 may comprise a right shoulder pulley 40, which may be attached to the T2 shaft, a right elbow pulley 42, which may be attached to the right forearm, and a band, belt or cable 44, which may transmit motion between the two pulleys 40, 42. The belt arrangement 38 may feature a constant or variable transmission ratio. As an example, the variable transmission ratio may be selected so that the orientation of the right forearm changes in a predefined manner as a function of the relative position of the right upper arm and the T2 shaft. However, any other suitable arrangement may be used.

Similarly, the right wrist 78 with a right end-effector B 80 may be coupled to the right forearm 76 via a rotary joint (left wrist joint), and rotationally constrained by another belt arrangement 96. The belt arrangement 96 may comprise a second right elbow pulley 98, which may be attached to the right upper arm 116, a right wrist pulley 100, which may be attached to the right wrist 78, and a band, belt or cable 102, which may transmit motion between the two pulleys 98, 100. The belt arrangement 96 may feature a variable transmission ratio. As an example, the variable transmission ratio may be selected so that the orientation of the right wrist changes in a predefined manner as a function of the relative angle of the right upper arm and the right forearm. However, any other suitable arrangement may be used.

As an example, the variable-transmission belt arrangements may be conveniently designed so that, as the arm extends from its retracted position to a station, the orientation of the end-effector gradually aligns with the radial path to the station and then remains unchanged relative to the radial path to the station. Consequently, the relative orientation of the end-effector may be the same when the arm is extended to stations in different radial locations.

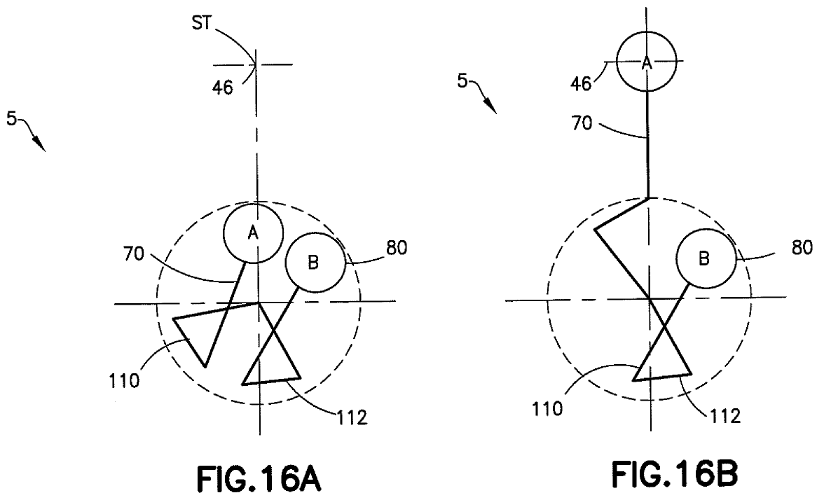

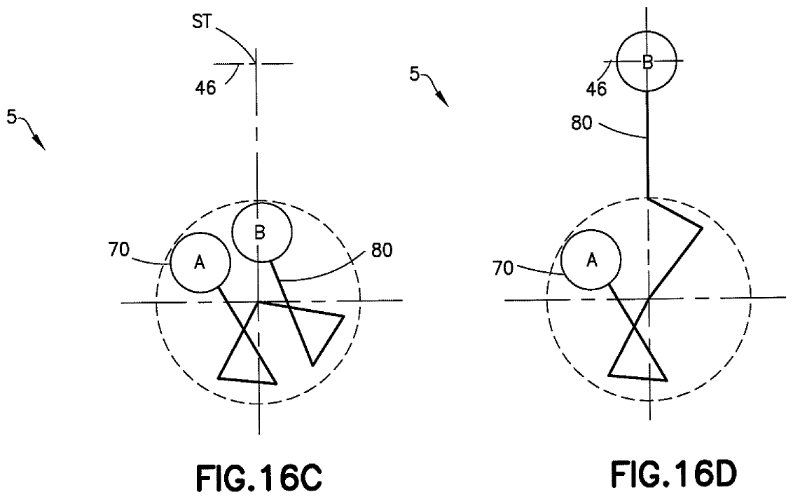

The T1, T2 and T3 shafts of the robot drive unit may be rotated so that the left end-effector A and right end-effector B can access various stations, as illustrated diagrammatically in FIGS. 15-16, which show diagrams of the robot 110 in an example semiconductor wafer processing system 5.

In order for the entire robot arm 112 to rotate, all drive shafts, i.e., T1, T2 and T3, need to move in the desired direction of rotation of the arm 112 by the same amount with respect to a fixed reference frame. This is depicted diagrammatically in FIGS. 15A-15B. In this particular example, the entire robot arm 112 rotates in the clockwise direction by 90 degrees.

In order for the left end-effector A 70 to extend from the retracted position of FIG. 16A to a station ST 46 along a predefined path, such as a straight-line radial path for example, as depicted diagrammatically in the example of FIGS. 16A-16B, shaft T1 may rotate in the clockwise direction while shaft T2 may be held stationary. As illustrated in the figures, the right end-effector B 80 may remain stationary as the left end-effector A 70 extends to the station ST 46. The variable-transmission belt arrangements may be conveniently designed so that the orientation of the left end-effector does not change with extension over the final portion of the move, which means that the relative orientation of the end-effector may be the same when extended to stations in different radial locations. The left end-effector A 70 may be retracted by rotating the T1 shaft backward in a similar manner.

In order for the right end-effector B 80 to extend from the retracted position of FIG. 16C to the same station ST 46 along a predefined path, such as a straight-line radial path for example, as depicted diagrammatically in the example of FIGS. 16C-16D, shafts T3 may rotate in the counterclockwise direction while shaft T2 may be held stationary. As illustrated in the figures, the left end-effector A 70 may remain stationary as the right end-effector B 80 extends to the station ST 46. The variable-transmission belt arrangements may be conveniently designed so that the orientation of the left end-effector does not change with extension over the final portion of the move, which means that the relative orientation of the end-effector may be the same when extended to stations in different radial locations. The right end-effector B 80 may be retracted by rotating the T3 shaft backward in a similar manner.

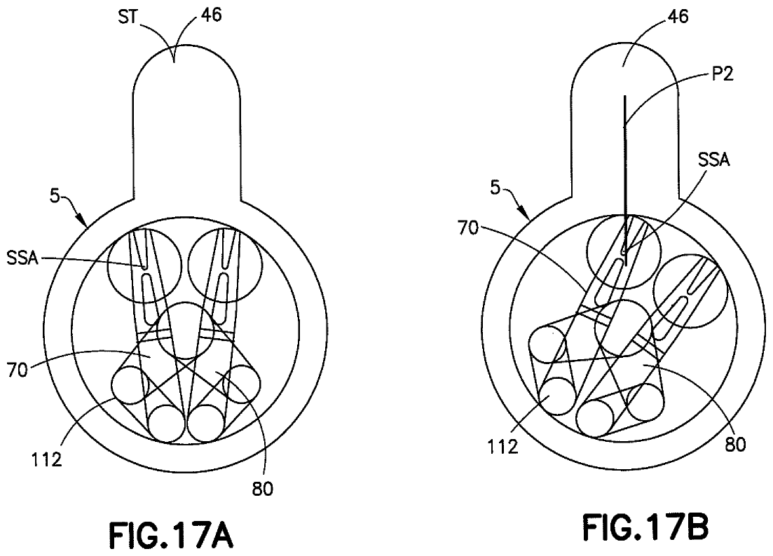

The extension motion from the retracted position of FIG. 16A to the extended position of FIG. 16B is further illustrated in FIGS. 17A-17D, which shows intermediate phases of the motion. FIGS. 17A-17D show the two different types of paths P1 and P2 which the substrate supporting area SSA of the first end effector 70 travels between the retracted first position shown in FIG. 17A to the extended position inside the substrate processing module 46 shown in FIG. 17D. The first path P1 is curved. The second path P2 is straight. In the first path P1 from FIG. 17A to FIG. 17B the SSA is moved from the retracted first position shown in FIG. 17A to the start of the second path P2 shown in FIG. 17B. From the start of the second path P2 shown in FIG. 17B, the SSA is then moved forward into the station 46 with the end effector 70 straightening out and the SSA traveling along the straight line of the second path P2.

The above operations may be utilized to pick/place a wafer from/to a station ST 46. A sequence of a pick operation with one end-effector followed by a place operation with the other end-effector may be used to quickly exchange a wafer at a station (rapid exchange operation). As an example, the left end-effector A 70 may be extended to the station ST 46, pick a wafer, and retract. The right end-effector B 80, which may carry another wafer, may then extend to the same station ST 46, place the wafer, and retract.

As depicted diagrammatically in FIG. 14, the robot drive unit may include a vertical lift mechanism 104 to control the vertical elevation of the robot arm 112, which may be used to access stations ST at different elevations, compensate for the vertical distance between the end-effectors of the robot arm if the end-effectors are not coplanar, and facilitate material pick/place operations.

Although the illustrations of the example embodiment show the robot 110 with the left upper arm below the right upper arm, and the left and right end-effectors are depicted at the same elevation (coplanar), the upper arms and end-effectors may be arranged in various configurations and elevations. Similarly, although the example embodiment shows the left upper arm of the robot 110 driven by the T1 shaft and the right upper arm of the robot 110 driven by the T3 shaft, any suitable driving schemes and transmission arrangements may be used. Furthermore, while straight lines are used to represent the example embodiment in the figures, the upper arms, forearms and end-effectors may feature any suitable shapes, for instance, to avoid interference with obstacles in the workspace of the robot.

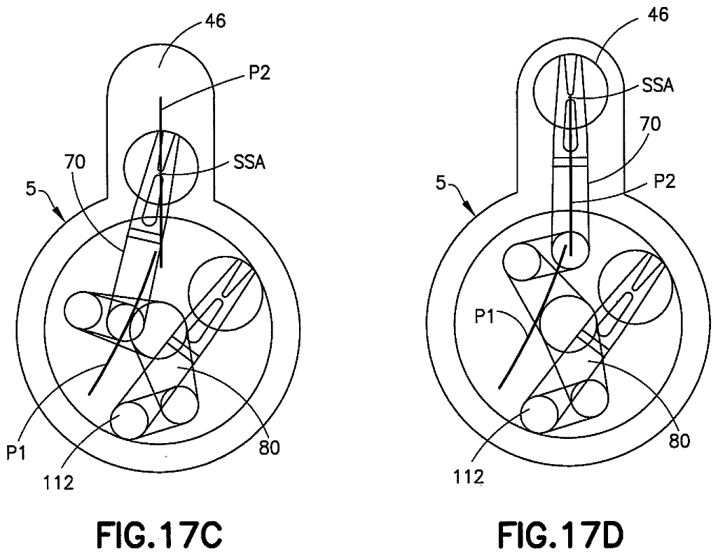

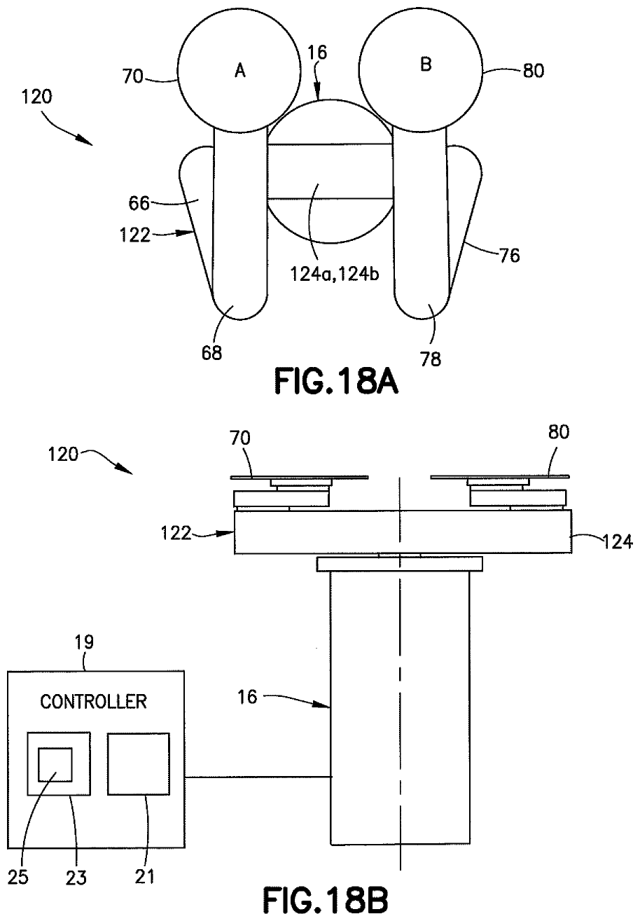

Another example embodiment of a robot with two end-effectors is depicted diagrammatically in FIGS. 18A-18B. FIG. 18A shows a top view of the robot 120 and FIG. 18B depicts a side view of the robot 120. The robot 120 in this embodiment comprises a robot drive unit 16 and a robot arm 122. The drive unit 16 is coupled to a controller 19 which may comprise, for example, at least one processor 21 and at least one memory 23 comprising computer code 25 for controlling the drive 16 and receiving sensor signals from sensors in the drive 16 as well as other sensors and inputs (not shown). The robot arm 122 may feature two linkages, i.e., a left linkage and a right linkage.

The left linkage, in this example embodiment, comprises an upper arm 124a, the left forearm 66 and the left wrist 68 with the left end-effector A 70. Similarly, the right linkage, in this example embodiment, comprises the upper arm 124b, the right forearm 76 and the right wrist 78 with the right end-effector B 80. In this example embodiment, the upper arms 124a, 124b of the left and right linkages are rigidly connected together, and can be viewed as a single shared link 124.

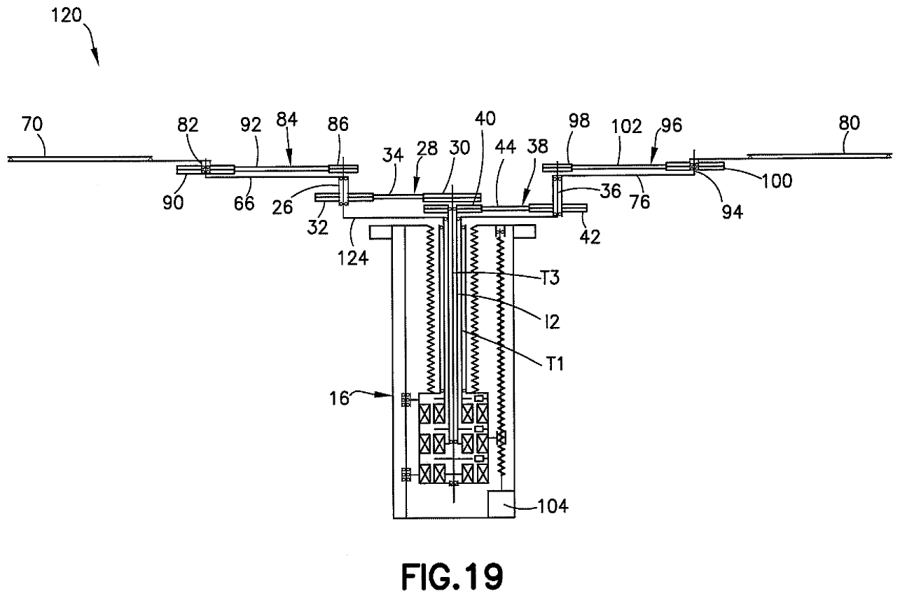

An example internal arrangement of the robot 120 is depicted diagrammatically in FIG. 19. The robot arm 122 may be driven by a robot drive unit 16 with a three-axis spindle with three coaxial shafts, e.g., an outer T1 shaft, a T2 shaft and an inner T3 shaft.

The upper arm 124 of the robot arm 122 may be attached directly to the T1 shaft. The left forearm 66 may be coupled to the upper arm 124 via a rotary joint (left elbow joint) 26, and actuated by the T2 shaft using a belt arrangement 28. The belt arrangement 28 may comprise a left shoulder pulley 30, which may be attached to the T2 shaft, a left elbow pulley 32, which may be attached to the left forearm 66, and a band, belt or cable 34, which may transmit motion between the two pulleys 30, 32.

The left wrist 68 with the left end-effector A 70 may be coupled to the left forearm 66 via a rotary joint (left wrist joint) 82, and rotationally constrained by another belt arrangement 84. The belt arrangement 84 may comprise a second left elbow pulley 86, which may be attached to the upper arm 124, a left wrist pulley 90, which may be attached to the left wrist 68, and a band, belt or cable 92, which may transmit motion between the two pulleys 86, 90. The belt arrangement 84 may feature a variable transmission ratio. As an example, the variable transmission ratio may be selected so that the orientation of the left wrist changes in a predefined manner as a function of the relative angle of the upper arm and the left forearm. However, any other suitable arrangement may be used.

The right linkage may be conceptually viewed as a mirror image of the left linkage. The right forearm 76 may be coupled to the upper arm 124 via a rotary joint (right elbow joint) 36, and actuated by the T3 shaft using a belt arrangement 38. The belt arrangement 38 may comprise a right shoulder pulley 40, which may be attached to the T3 shaft, a right elbow pulley 42, which may be attached to the right forearm 76, and a band, belt or cable 44, which may transmit motion between the two pulleys 40, 42.

The right wrist 78 with the right end-effector B 80 may be coupled to the right forearm 76 via a rotary joint (right wrist joint) 94, and rotationally constrained by another belt arrangement 96. The belt arrangement 96 may comprise a second right elbow pulley 98, which may be attached to the upper arm 76, a right wrist pulley 100, which may be attached to the right wrist 78, and a band, belt or cable 102, which may transmit motion between the two pulleys 98, 100. The belt arrangement 96 may feature a variable transmission ratio. As an example, the variable transmission ratio may be selected so that the orientation of the right wrist 78 changes in a predefined manner as a function of the relative angle of the right upper arm 124 and the right forearm 76. However, any other suitable arrangement may be used.

As an example, the variable-transmission belt arrangements 28, 38, 84, 96 may be conveniently designed so that, as the arm extends from its retracted position to a station, the orientation of the end-effector changes in a suitable predefined manner in the initial portion of the extension motion and then follows the radial path to the station in the final portion of the extension motion. More specifically, as an example, the variable-transmission belt arrangements may be designed so that, as the arm extends from its retracted position to a station, the orientation of the end-effector remains substantially parallel with the radial path to the station until the forearm rotates directly above the upper arm and then follows the radial path to the station.

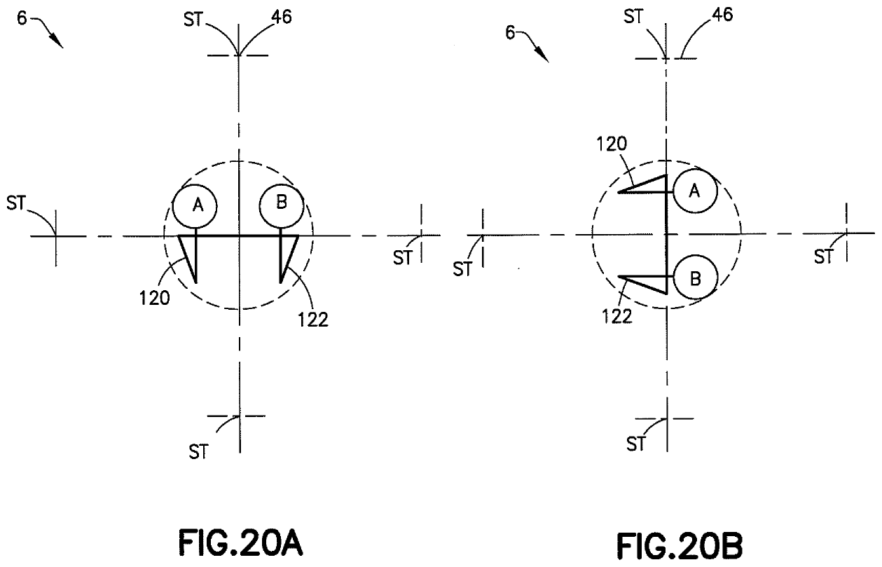

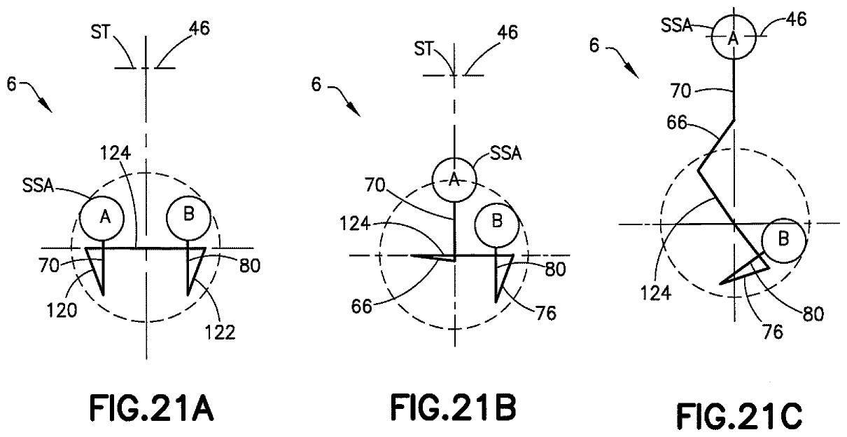

The T1, T2 and T3 shafts of the robot drive unit may be rotated so that the left end-effector A 70 and right end-effector B 80 can access various stations, as illustrated diagrammatically in FIGS. 20-21, which show diagrams of the robot 120 in an example semiconductor wafer processing system 6.

In order for the entire robot arm 122 to rotate, all drive shafts, i.e., T1, T2 and T3, need to move in the desired direction of rotation of the arm 122 by the same amount with respect to a fixed reference frame. This is depicted diagrammatically in FIGS. 20A-20B. In this particular example, the entire robot arm 122 rotates in the clockwise direction by 90 degrees.

In order for the left end-effector A 70 to extend from the common retracted position of FIG. 21A to the partially extended position of FIG. 21B, shaft T2 may rotate in the counterclockwise direction while shaft T1 may be held stationary. The variable-transmission belt arrangements may be conveniently designed so that the orientation of the left end-effector 80 may remain parallel with the starting orientation and/or the radial path to the station ST 46 during the move to the partially extended position of FIG. 21B. In order to complete the extension from the partially extended position of FIG. 21B to the station ST 46 along a predefined path, such as a straight-line radial path for example, as depicted diagrammatically in the example of FIG. 21C, shafts T2 may rotate in the counterclockwise direction while shaft T1 may rotate in the clockwise direction. As illustrated in the figures, the right end-effector B 80 may rotate as the left end-effector A 70 extends to the station ST 46. The left end-effector A 70 may be retracted by rotating the T1 and T2 shafts backward in a similar manner.

In order for the right end-effector B 80 to extend from the common retracted position of FIG. 21A to the partially extended position of FIG. 21D, shaft T3 may rotate in the clockwise direction while shaft T1 may be held stationary. The variable-transmission belt arrangements may be conveniently designed so that the orientation of the right end-effector may remain parallel with the starting orientation and/or the radial path to the station ST 46 during the move to the partially extended position of FIG. 21D. In order to complete the extension from the partially extended position of FIG. 21D to the station ST 46 along a predefined path, such as a straight-line radial path for example, as depicted diagrammatically in the example of FIG. 21E, shafts T3 may rotate in the clockwise direction while shaft T1 may rotate in the counterclockwise direction. As illustrated in the figure, the left end-effector A 70 may rotate as the right end-effector B 80 extends to the station. The right end-effector B 80 may be retracted by rotating the T1 and T3 shafts backward in a similar manner.

The above operations may be utilized to pick/place a wafer from/to a station. A sequence of a pick operation with one end-effector followed by a place operation with the other end-effector may be used to quickly exchange a wafer at the station (rapid exchange operation). As an example, the left end-effector A 70 may be extended to the station, pick a wafer, and retract. The right end-effector B 80, which may carry another wafer, may then extend to the same station, place the wafer, and retract.

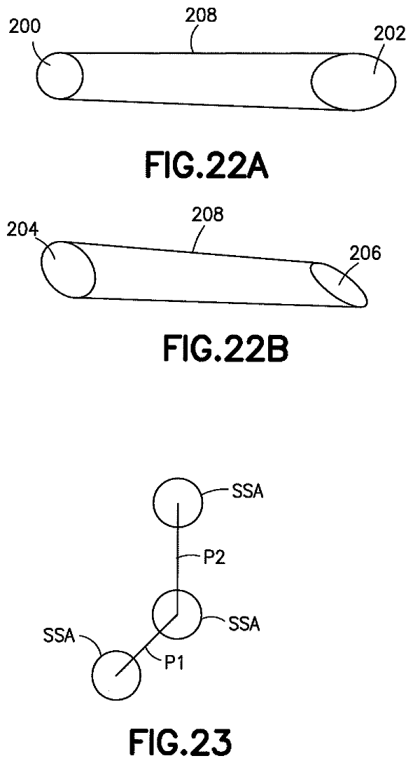

The extension motion from the retracted position of FIG. 21A to the extended position of FIG. 21C illustrates two different types of paths P1 and P2 and motions which the substrate supporting area SSA of the first end effector 70 travels between the retracted first position shown in FIG. 21A to the extended position inside the substrate processing module 46 shown in FIG. 21C. Referring also to FIG. 23, the first path P1 is straight, but may be curved as in the example shown in FIGS. 17A-17D. The second path P2 is straight. In the first path P1 from FIG. 21A to FIG. 21B the SSA is moved from the retracted first position shown in FIG. 21A to the start of the second path P2 shown in FIG. 21B. From the start of the second path P2 shown in FIG. 21B, the SSA is then moved forward into the station 46 with the end effector 70 being straight during the travel along the second path and the SSA traveling along the straight line of the second path P2.

As depicted diagrammatically in FIG. 19, the robot drive unit 16 may include a vertical lift mechanism 104 to control the vertical elevation of the robot arm 122, which may be used to access stations ST at different elevations, compensate for the vertical distance between the end-effectors of the robot arm if the end-effectors are not coplanar, and facilitate material pick/place operations.

Although the illustrations of the example embodiment show the robot 120 in the retracted position with the left and right end-effectors 70, 80 oriented in a substantially parallel manner, any suitable orientation of the end-effectors may be used. Similarly, although the example embodiment shows the left forearm 66 of the robot driven by the T2 shaft and the right forearm 76 of the robot driven by the T3 shaft, any suitable driving schemes and transmission arrangements may be used. Furthermore, while straight lines are used to represent the example embodiment in the figures, the upper arms, forearms and end-effectors may feature any suitable shapes, for instance, to avoid interference with obstacles in the workspace of the robot.

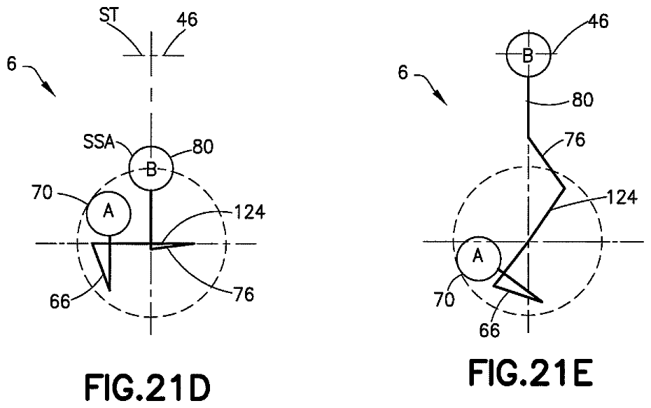

As noted above, any of the belt arrangement may feature a constant or variable transmission ratio, for example, implemented through the use of circular and/or non-circular pulleys. FIGS. 22A-22B show some examples of a circular pulley 200 and non-circular pulleys 202, 204, 206 connected by bands/belts 208. These are merely examples and should not be considered as limiting. Other suitably sized and shaped non-circular pulleys could be provided.

Although the examples described above include robot drives having only three coaxial drive shafts and only three motors for rotating those coaxial drive shafts, in alternate examples more than three drive shafts and more than three motors could be provided.

An example embodiment may be provided in an apparatus comprising a controller comprising a processor and a memory comprising computer code; a robot drive coupled to the controller, where the controller is configured to control actuation of the robot drive; a robot arm connected to the robot drive, where the robot arm comprises links including an upper arm, a first forearm connected to a first end of the upper arm, a second forearm connected to a second opposite end of the upper arm, a first end effector connected to the first forearm and a second end effector connected to the second forearm; and a transmission connecting the robot drive to the first and second forearms and the first and second end effectors, where the transmission is configured to rotate the first and second forearms relative to the upper arm and rotate the first and second end effectors on their respective first and second forearms, where the upper arm is substantially rigid such that movement of the upper arm by the robot drive moves both the first and second forearms in opposite directions, where the controller and the transmission are configured to coordinate movement and rotation of the links relative to one another to move the end effectors into and out of a station comprising: moving the first forearm relative to the upper arm, while the upper arm remains substantially stationary, to move the first end effector into an entrance path of the station, and subsequently rotating the upper arm and the first forearm to move the first end effector along the entrance path in a substantially straight line into the station.

The robot drive may comprise a plurality of motors and a plurality of coaxial drive shafts, where a center of the upper arm is mounted to a first one of the drive shafts. The plurality of coaxial drive shafts may comprise only three coaxial drive shafts and the plurality of motors may comprise only three motors for axially rotating the three coaxial drive shafts. The upper arm may have an effective length between the center of the upper arm and the first drive shaft which is substantially equal to an effective length of the first forearm between the upper arm and the first end effector. The transmission may comprise a first drive belt arrangement connecting a second one of the drive shafts to the first forearm and a second drive belt arrangement connecting the first forearm to the first end effector, where the second drive belt arrangement may comprise a variable transmission belt drive with at least one non-circular pulley. The transmission may comprise a third drive belt arrangement connecting a third one of the drive shafts to the second forearm and a fourth drive belt arrangement connecting the second forearm to the second end effector, where the fourth drive belt arrangement may comprise a variable transmission belt drive with at least one non-circular pulley. The transmission may comprise a first mechanical connection of the first end effector with the first forearm and a second mechanical connection of the second end effector with the second forearm which each may comprise a band drive having at least one non-circular pulley, and each of the first and second mechanical connections, including their at least one non-circular pulley, are configured to limit movement of the first and second end effectors on their respective first and second forearm such that the mechanical connections allow only straight movement of the first end effector relative to the drive when both the upper arm is rotated and the first forearm is rotated relative to the upper arm. The controller and the transmission may be configured to coordinate movement and rotation of the links relative to one another to provide a first translation motion of the first end effector in a lateral direction into an entrance path of a substrate processing module while the upper arm remains substantially stationary and a subsequent second translation motion of the first end effector, angled relative to the first translation motion, when both the first forearm and the upper arm are rotated to move the first end effector along the entrance path in the substantially straight line into the station.

An example method may comprise connecting a controller to a robot drive; connecting an upper arm to a first drive shaft of the robot drive; connecting a first forearm to an end of an upper arm; connecting a second forearm to an opposite end of the upper arm; connecting a first end effector to the first connecting a second end effector to the second forearm; connecting a first transmission belt arrangement between a second drive shaft of the robot drive and the first forearm; connecting a second transmission belt arrangement between the first forearm and the first end effector, where the second transmission belt arrangement is configured to rotate the first end effector relative to the first forearm when the first forearm is rotated relative to the upper arm, where the controller and the transmission belt arrangements are configured to coordinate movement of the upper arm and the first forearm on the upper arm relative to each another to move the first end effector into a station comprising: a first path comprising moving the first forearm relative to the upper arm, while the upper arm remains substantially stationary, to move the first end effector into a starting location of a second entrance path for the station, and the second entrance path comprising subsequently rotating the upper arm and the first forearm on the upper arm to move the first end effector along the second entrance path in a substantially straight line into the station.

The robot drive may comprise a plurality of motors and a plurality of coaxial drive shafts, where a center of the upper arm is mounted to a first one of the drive shafts, where rotating the upper arm may comprise rotating the upper arm about the center of the upper arm. The plurality of coaxial drive shafts may comprise only three coaxial drive shafts and the plurality of motors may comprise only three motors which axially rotate the three coaxial drive shafts. The upper arm may have an effective length between the center of the upper arm and the first drive shaft which is substantially equal to an effective length of the first forearm between the upper arm and the first end effector. The connecting of the first transmission belt arrangement may comprise connecting the second drive shaft to the first forearm by a first belt and a first set of pulleys, where the connecting of the second transmission belt arrangement may comprise connecting the first forearm to the first end effector by a second belt and a second set of pulleys, and where the second set of pulleys may comprise at least one non-circular pulley to provide a variable transmission belt drive. The method may further comprise connecting a third drive shaft of the robot drive to the second forearm by a third belt and a third set of pulleys, connecting the second forearm to the second end effector by a fourth belt and a fourth set of pulleys, and where the fourth set of pulleys may comprise at least one non-circular pulley to provide a variable transmission belt drive. The second transmission belt arrangement may comprise a mechanical connection of the first end effector with the first forearm which comprises a band drive having at least one non-circular pulley, and the mechanical connection, including the at least one non-circular pulley, may limit movement of the first end effectors on the first forearm such that the mechanical connection allows only straight movement of the first end effector relative to the drive when both the upper arm is rotated and the first forearm is rotated relative to the upper arm.

An example method may comprise moving a first end effector along a first path from a first location to a second location, where the second location is a start of a subsequent second substantially straight entrance path into a substrate processing module, where the first end effector is connected to an end of a first forearm of a robot arm, where the first end effector is moved along the first path by rotating the first forearm on an upper arm of the robot arm by a robot drive while the upper arm remains substantially stationary, and rotating the first end effector relative to the first forearm as the first forearm is rotated on the upper arm, where the robot arm comprises a transmission belt arrangement connected between the first end effector and the first forearm to automatically mechanically rotate the first end effector relative to the first forearm as the first forearm is rotated on the upper arm; and moving the first end effector from the second location into the substrate processing module along the second substantially straight entrance path, where the second substantially straight entrance path is maintained by rotating the upper arm by the robot drive to move the first forearm towards the substrate processing module and simultaneously rotating the first forearm on the upper arm while the transmission belt arrangement automatically mechanically rotates the first end effector relative to the first forearm, as the first forearm is rotated on the upper arm, to maintain the first end effector in a substantially straight line into the substrate processing module.

The robot drive may comprise a plurality of motors and a plurality of coaxial drive shafts, where a center of the upper arm is mounted to a first one of the drive shafts, where rotating the upper arm may comprise rotating the upper arm about the center of the upper arm. The plurality of coaxial drive shafts may comprise only three coaxial drive shafts and the plurality of motors comprises only three motors which axially rotate the three coaxial drive shafts. The upper arm may have an effective length between the center of the upper arm and the first drive shaft which is substantially equal to an effective length of the first forearm between the upper arm and the first end effector. The transmission belt arrangement may comprise a first belt and a first set of pulleys, and where the first set of pulleys may comprise at least one non-circular pulley to provide a variable transmission belt drive when the first end effector is rotated on first forearm.

An example embodiment may be provided in an apparatus comprising means for moving a first end effector along a first path from a first location to a second location, where the second location is a start of a subsequent second substantially straight entrance path into a substrate processing module, where the first end effector is connected to an end of a first forearm of a robot arm, where the first end effector is moved along the first path by rotating the first forearm on an upper arm of the robot arm by a robot drive while the upper arm remains substantially stationary, and rotating the first end effector relative to the first forearm as the first forearm is rotated on the upper arm, where the robot arm comprises a transmission belt arrangement connected between the first end effector and the first forearm to automatically mechanically rotate the first end effector relative to the first forearm as the first forearm is rotated on the upper arm; and means for moving the first end effector from the second location into the substrate processing module along the second substantially straight entrance path, where the second substantially straight entrance path is maintained by rotating the upper arm by the robot drive to move the first forearm towards the substrate processing module and simultaneously rotating the first forearm on the upper arm while the transmission belt arrangement automatically mechanically rotates the first end effector relative to the first forearm, as the first forearm is rotated on the upper arm, to maintain the first end effector in a substantially straight line into the substrate processing module.

It should be understood that the foregoing description is only illustrative. Various alternatives and modifications can be devised by those skilled in the art. For example, features recited in the various dependent claims could be combined with each other in any suitable combination (s). In addition, features from different embodiments described above could be selectively combined into a new embodiment. Accordingly, the description is intended to embrace all such alternatives, modifications and variances which fall within the scope of the appended claims.

1. An apparatus comprising:
a first upper arm rotatable about a first shoulder axis;
a second upper arm rotatable about the first shoulder axis;
a first forearm rotatably connected to the first upper arm;
a second forearm rotatably connected to the second upper arm;
a first end effector rotatably connected to the first forearm, where the first end effector is configured to support at least one substrate thereon; and
a second end effector rotatably connected to the second forearm where the first end effector is configured to support at least one substrate thereon;
where the first and second upper arms are configured to rotate in different first and second horizontal planes, where the first and second forearms are configured to rotate in a common different third horizontal plane, and where the first and second end effectors are configured to rotate in a common different fourth horizontal plane, where the first and second end effectors in retracted positions are angled relative to each other with substrate holding areas of the first and second end effectors being located laterally opposite each other.

2. A method comprising:
connecting a first upper arm to a first drive shaft of a robot drive, where the first upper arm is rotatably along a first horizontal plane;
connecting a second upper arm to a second drive shaft of the robot drive, where the second upper arm is rotatably along a spaced different second horizontal plane;
connecting a first forearm to an end of the first upper arm, where the first forearm is rotatably along a different third horizontal plane;
connecting a second forearm to an end of the second upper arm, where the second forearm is rotatably along the third horizontal plane spaced from the first and second horizontal planes;
connecting a first end effector to the first forearm, where the first end effector is rotatably along a different fourth horizontal plane spaced from the first, second and third horizontal planes;
connecting a second end effector to the second forearm, where the second end effector is rotatably along the fourth horizontal plane,
where the first and second end effectors, in retracted positions, are angled relative to each other with substrate holding areas of the first and second end effectors being located laterally opposite each other.

3. A method comprising:
providing a robot arm assembly comprising:
a first upper arm rotatable about a first shoulder axis;
a second upper arm rotatable about the first shoulder axis;
a first forearm rotatably connected to the first upper arm;
a second forearm rotatably connected to the second upper arm;
a first end effector rotatably connected to the first forearm, where the first end effector is configured to support at least one substrate thereon; and
a second end effector rotatably connected to the second forearm where the first end effector is configured to support at least one substrate thereon;
where the first and second end effectors, in retracted positions, are angled relative to each other with substrate holding areas of the first and second end effectors being located laterally opposite each other;
moving the first and second upper arms in substantial unison to position a first substrate holding area of the first end effector in a line with an intended substantially straight path of extension of the first substrate holding area from a retracted position to an extended position;
moving a substrate on the first end effector in the intended substantially straight path of extension from the retracted position to the extended position comprising:
rotating the first upper arm about the first shoulder axis,
rotating the first forearm on the first upper arm, and
rotating the first end effector on the first forearm.

4. The method as in claim 3 where the upper arms are configured to rotate in different first and second horizontal planes, where the first and second forearms are configured to rotate in a common different third horizontal plane, and where the first and second end effectors are configured to rotate in a common different fourth horizontal plane

5. A non-transitory program storage device readable by an apparatus, tangibly embodying a program of instructions executable with the apparatus for performing operations, the operations comprising the moving as claimed in claim 3.

6. The apparatus as claimed in claim 1 where, in the retracted positions, the first and second end effectors are located on opposite sides of the first shoulder axis.

7. The apparatus as claimed in claim 1 where, in the retracted positions, the first and second end effectors have first ends at respective rotatably connections to the first and second forearms which are located closer together than opposite second ends of the first and second end effectors.

8. The apparatus as claimed in claim 7 where, in the retracted positions, first ends of the first and second end effectors and the second ends of the first and second end effectors are located on opposite sides of the first shoulder axis.

9. The apparatus as claimed in claim 7 where, in the retracted positions, the first upper arm is angled relative to the second upper arm with an acute angle facing the first ends of the first and second end effectors.

10. The apparatus as claimed in claim 9 where the first forearm has a shorter length than the first upper arm, and the second forearm has a shorter length than the second upper arm.

11. The apparatus as claimed in claim 10 where the first end effector has a longer length than the first upper arm, and the second end effector has a longer length than the second upper arm.

12. The apparatus as claimed in claim 11 where, when the first upper arm, the first forearm and the first end effector are in an extended position and the second upper arm, the second forearm and the second end effector are in the retracted position, the first and second upper arms are substantially aligned.

13. The apparatus as claimed in claim 12 where the first upper arm, the first forearm and the first end effector are configured to move a substrate holding area on the first end effector from the retracted position to the extended position along a substantially straight path aligned with the shoulder axis.

14. The apparatus as claimed in claim 13 where the apparatus is configured such that the second upper arm, the second forearm and the second end effector do not move relative to one another retained in the retracted position as the first upper arm, the first forearm and the first end effector are moved to the extended position.

15. The apparatus as claimed in claim 14 where, in the retracted positions the first end effector crosses over the first upper arm and the second end effector crosses over the second upper arm.

16. The apparatus as claimed in claim 15 where the apparatus is configured such that, to extend the first end effector from the retracted position to the extended position, when the first and second end effectors are located on the opposite sides of the first shoulder axis, the first and second upper arms are configured to rotate together about the shoulder axis to substantially align the substrate holding area of the first end effector with the substantially straight path aligned with the shoulder axis, and then rotate the first upper arm relative to extend the substrate holding area of the first end effector along the substantially straight path while the second upper arm remains stationary.

17. The apparatus as claimed in claim 16 where the apparatus is configured to:
limit location of the first end effector to within a circular area unless the first end effector is being moved between its retracted position and its extended position, and
limit location of the second end effector to within the circular area unless the second end effector is being moved between its retracted position and its extended position,
where the circular area is defined by a distance between the shoulder axis and an outer most location of substrates on the substrate holding areas of the first and second end effectors when the first and second end effectors are at their retracted positions.

18. The apparatus as claimed in claim 1 where the first and second upper arms, in their retracted positions, are angled relative to each other at an angle of about 72 degrees.

19. The apparatus as claimed in claim 1 where the first upper arm and the first forearm, in their retracted positions, are angled relative to each other at an angle of about 67 degrees.

20. The apparatus as claimed in claim 1 where the first forearm and the first end effector, in their retracted positions, are angled relative to each other at an angle of about 55 degrees.

21. The apparatus as claimed in claim 1 where the first upper arm and the first end effector, in their retracted positions, are angled relative to each other at an angle of about 122 degrees, where the first end effector crosses over the first upper arm.

22. The apparatus as claimed in claim 1 where the first and second end effectors, in their retracted positions, are angled relative to each other at an angle of about 8 degrees, where the first end effector crosses over the first upper arm.

23. An apparatus comprising:
a first upper arm rotatable about a first shoulder axis;
a second upper arm rotatable about the first shoulder axis;
a first forearm rotatably connected to the first upper arm;
a second forearm rotatably connected to the second upper arm;
a first end effector rotatably connected to the first forearm, where the first end effector is configured to support at least one substrate thereon; and
a second end effector rotatably connected to the second forearm where the first end effector is configured to support at least one substrate thereon;
where the first and second end effectors, in retracted positions, are angled relative to each other with substrate holding areas of the first and second end effectors being located laterally adjacent each other.

24. The apparatus as claimed in claim 23 where, in the retracted positions, the first and second end effectors are located on opposite sides of the first shoulder axis, where the first and second end effectors have first ends at respective rotatably connections to the first and second forearms which are located closer together than opposite second ends of the first and second end effectors, where first ends of the first and second end effectors and the second ends of the first and second end effectors are located on opposite sides of the first shoulder axis.

25. The apparatus as claimed in claim 24 where, in the retracted positions, the first upper arm is angled relative to the second upper arm with an acute angle facing the first ends of the first and second end effectors, where the first forearm has a shorter length than the first upper arm, and the second forearm has a shorter length than the second upper arm, where the first end effector has a longer length than the first upper arm, and the second end effector has a longer length than the second upper arm.

26. The apparatus as claimed in claim 23 where, when the first upper arm, the first forearm and the first end effector are in an extended position and the second upper arm, the second forearm and the second end effector are in the retracted position, the first and second upper arms are substantially aligned, where the first upper arm, the first forearm and the first end effector are configured to move a substrate holding area on the first end effector from the retracted position to the extended position along a substantially straight path aligned with the shoulder axis, where the is apparatus configured such that the second upper arm, the second forearm and the second end effector do not move relative to one another retained in the retracted position as the first upper arm, the first forearm and the first end effector are moved to the extended position.

27. The apparatus as claimed in claim 23 where, in the retracted positions the first end effector crosses over the first upper arm and the second end effector crosses over the second upper arm, where the apparatus is configured such that, to extend the first end effector from the retracted position to the extended position, when the first and second end effectors are located on the opposite sides of the first shoulder axis, the first and second upper arms are configured to rotate together about the shoulder axis to substantially align the substrate holding area of the first end effector with the substantially straight path aligned with the shoulder axis, and then rotate the first upper arm relative to extend the substrate holding area of the first end effector along the substantially straight path while the second upper arm remains stationary, where the apparatus is configured to:
limit location of the first end effector to within a circular area unless the first end effector is being moved between its retracted position and its extended position, and
limit location of the second end effector to within the circular area unless the second end effector is being moved between its retracted position and its extended position, where the circular area is defined by a distance between the shoulder axis and an outer most location of substrates on the substrate holding areas of the first and second end effectors.

28. The apparatus as claimed in claim 23 where the first and second upper arms, in their retracted positions, are angled relative to each other at an angle of about 72 degrees, where the first upper arm and the first forearm, in their retracted positions, are angled relative to each other at an angle of about 67 degrees, where the first forearm and the first end effector, in their retracted positions, are angled relative to each other at an angle of about 55 degrees, where the first upper arm and the first end effector, in their retracted positions, are angled relative to each other at an angle of about 122 degrees, where the first end effector crosses over the first upper arm, where the first and second end effectors, in their retracted positions, are angled relative to each other at an angle of about 8 degrees, where the first end effector crosses over the first upper arm.

29. An apparatus comprising:
a first upper arm rotatable about a first shoulder axis;
a second upper arm rotatable about the first shoulder axis;
a first forearm rotatably connected to the first upper arm;
a second forearm rotatably connected to the second upper arm;
a first end effector rotatably connected to the first forearm, where the first end effector is configured to support at least one substrate thereon; and
a second end effector rotatably connected to the second forearm where the first end effector is configured to support at least one substrate thereon;
where, in a retracted position of the first end effector, the first end effector crosses over the first upper arm, and
where the first and second end effectors, in their retracted positions, are angled relative to each other with substrate holding areas of the first and second end effectors being located laterally opposite each other.

30. The apparatus as claimed in claim 29 where, in a retracted position of the first end effector, the second end effector crosses over the second upper arm.

31. The apparatus as claimed in claim 29 where the first and second upper arms are configured to rotate in different first and second horizontal planes, where the first and second forearms are configured to rotate in a common different third horizontal plane, and where the first and second end effectors are configured to rotate in a common different fourth horizontal plane.

32. The method as claimed in claim 3 comprising, to extend the first end effector from the retracted position to the extended position, when the first and second end effectors are located on opposite sides of the first shoulder axis:
rotating the first and second upper arms together about the shoulder axis to substantially align the substrate holding area of the first end effector with the substantially straight path aligned with the shoulder axis; and
subsequently rotating the first upper arm relative to extend the substrate holding area of the first end effector along the substantially straight path while the second upper arm remains stationary.

33. The method as claimed in claim 32 comprising:
limiting location of the first end effector to within a circular area unless the first end effector is being moved between its retracted position and its extended position, and
limiting location of the second end effector to within the circular area unless the second end effector is being moved between its retracted position and its extended position, where the circular area is defined by a distance between the shoulder axis and an outer most location of substrates on the substrate holding areas of the first and second end effectors when the first and second end effectors are at their retracted positions.
